(19) United States
(12) Patent Application Publication
(10) Pub. No.: US 2005/0189627 A1
(43) Pub. Date: Sep. 1, 2005

(54) Method of surface mounting a semiconductor device

(76) Inventors: Fujio Ito, Hanno (JP); Hiromichi Suzuki, Nishishinkoiwa (JP); Takashi Miwa, Fussa (JP); Tokuji Toida, Hamura (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/065,108

(22) Filed: Feb. 25, 2005

(30) Foreign Application Priority Data
Feb. 27, 2004 (JP) 2004-053728

(51) Int. Cl. H01L 23/495

(52) U.S. Cl. 257/666

(57) ABSTRACT

A surface mounting method for mounting semiconductor devices suppresses solder peeling defects which tried to occur during mounting. The method used for mounting semiconductor devices includes a process for preparing the semiconductor devices by obtaining multiple terminals by exposing a section of each of multiple leads protruding from a rear side of the plastic casing, and forming a layer of solder by solidifying a molten solder material; a process for supplying a solder paste material to multiple electrodes on a printed circuit board; and a process for melting the solder paste of the multiple electrodes and connecting each of the multiple terminals with the multiple electrodes.

### CROSS-REFERENCE TO RELATED APPLICATION

The present application claims priority from Japanese patent application No. 2004-053728, filed on Feb. 27, 2004, the content of which is hereby incorporated by reference into this application.

### BACKGROUND OF THE INVENTION

The present invention relates in general to surface mounting technology for use in the mounting of semiconductor devices and also to the semiconductor devices to be mounted; and, the present invention relates in particular to a technology that is effective for the mounting of semiconductor devices containing external terminals that are obtained by exposing a section of the leads from the rear side of the semiconductor package.

In semiconductor devices that are made up of integrated circuits mounted on a semiconductor chip and sealed in a plastic casing (package), various package structures have been proposed and developed into products. One of those structures is a semiconductor device known as the QFN (Quad Flatpack Non-Leaded Package) type. This QFN type semiconductor device has a package structure wherein the semiconductor chip electrodes and the electrically connected leads are exposed from the rear side of the plastic casing (package). Therefore, the QFN type semiconductor device has a more compact plane area size compared, for example, to a semiconductor device called the QFP (Quad Flatpack Package), which has a package structure wherein the semiconductor chip electrodes and the electrically connected leads are made to protrude from the sides of the plastic casing and are bent into a specified shape.

A lead frame is used in the manufacture of the QFN type semiconductor device. The lead frame is manufactured by etching or stamping it from a metal plate with a precision press, and a specified pattern is then formed. The lead frame is a frame body consisting of an outer frame section and an inner frame section that contain numerous component forming regions. Chip support pieces (tabs, diebonds, chip mounting sections) for mounting the semiconductor chip and numerous leads facing the tips (one end) around these chip support pieces are installed on these component forming regions. These chip support pieces are supported by a lead that is suspended from the lead frame body. One end of the leads (tip) and the end on the opposite side are supported by the lead frame body.

When using this type of lead frame to manufacture a QFN type semiconductor device, the chip support pieces of the lead frame are clamped to the semiconductor chip. The semiconductor chip electrodes, the leads and the conductive wires are later electrically connected. The semiconductor chip, wires, chip support pieces and suspension (hanging) leads are later sealed in, and the plastic casing is formed. Excess portions of the lead frame are later cut off.

The plastic casing for the QFN type semiconductor device is formed by a transfer molding method, which is ideal for mass production. To form the package by transfer molding, the lead frame is positioned between the upper mold and lower mold of the mold (or cast) device so that the semiconductor chip, leads, chip support pieces, suspension leads and bonding wire are positioned inside the cavity (section to be filled with resin) of the mold device (or cast). Thermosetting resin is then injected inside the cavity of the mold device.

Technology for the QFN type semiconductor device has been disclosed, for example, in Japanese Unexamined Patent Publication No. 2001-189410 and in U.S. Pat. No. 3,072,291.

### SUMMARY OF THE INVENTION

After evaluating results obtained from investigating QFN devices, the present inventors have discovered the following problems with the related art.

The QFN type semiconductor device is mounted on a printed circuit board along with other surface-mounted components. The QFN device and the board are then assembled into miniature electronic devices, such as cellular telephones, portable information processor terminals, portable personal computers, etc. The reflow soldering method is commonly used to achieve good productivity when mounting the QFN type semiconductor device and other components. The reflow soldering method uses a technique, such as screen printing, to collectively solder the surface-mounted components to the electrode pads (lands, footprints, contact terminals) on the printed circuit board in one batch using a pre-positioned melted solder paste material.

In the mounting process, the QFN semiconductor device is exposed to high temperatures. These high temperatures accelerate the hardening reaction of the thermosetting resin (plastic casing) that seals the semiconductor chip so that a curvature (warp) occurs in the package (plastic casing). This package curvature generates stress on the solder connection (the section joining the QFN semiconductor device terminals via the solder on the printed circuit board electrode pads) after component mounting. This stress causes problems (solder peeling defects), such as the external terminal of the QFN semiconductor device peeling from the electrode pads of the printed circuit board.

Package sizes for QFN semiconductor devices tend to become large due to the large number of pins needed to keep pace with demands for high performance and a multiple function capability. However, as package sizes become larger, this package curvature also increases during the mounting process. In the QFN semiconductor device, which has a large package size, these solder peeling defects are especially prone to occur.

These solder peeling defects can be suppressed by making the solder layer between the external terminals on the QFN semiconductor device and the electrode pads of the printed circuit board thicker (solder layer thickness after mounting). One method considered for increasing the solder layer thickness after component mounting is achieved by increasing the solder paste material during mounting.

However, this reflow soldering method usually includes a soldering of the other surface mounted components in one batch along with the QFN semiconductor device on the printed circuit board. Therefore, if the solder paste material has been thickened for the QFN semiconductor device in the mounting area, then the solder paste material for the other surface mounted components also will be thickened. Therefore, a phenomena, such as the Chip Standing Phenomenon and Manhattan Phenomenon, are prone to easily occur in the other surface mounted components, for example, chip type electronic components, such as chip resistors and chip capacitors that tend to stand erect due to the surface tensility of the solder. Therefore, suppressing solder peeling defects in QFN semiconductor devices by thickening the solder paste material is not satisfactory.

Therefore, the present inventors, while taking note of the external terminals on the QFN semiconductor device, have contrived the present invention.

The present invention has an object of providing a technology for suppressing solder peeling defects in semiconductor devices during mounting.

The present invention has a further object of providing a technology capable of improving the productivity in mounting semiconductor devices.

The above and other related objects and new features will become more apparent from the following detailed description and the accompanying work drawings.

Typical examples of the present invention disclosed in this application can be summarized as follows.

(1) A mounting method for semiconductor devices including;
a process (a) for preparing the semiconductor devices by obtaining multiple terminals by exposing a section of each of multiple leads protruding from a rear surface of a plastic casing, and forming a layer of solder by solidifying a molten solder material;
and a process (b) for supplying a solder paste material to multiple electrodes on a printed circuit board; and
a process (c) for melting the solder paste material of multiple electrodes and connecting each of the multiple terminals with the multiple electrodes.

(2) The mounting method for semiconductor devices according to the above Example (1) wherein,
in the above process (c), the solder layer of each of the multiple terminals is melted along with the solder paste material.

(3) A mounting method for semiconductor devices according to the above Example (1) wherein,
when the solder layer height is set as a, and a solder layer width is set as b, the solder layer attains an arc shape of a/b≦½.

(4) The semiconductor device includes multiple terminals formed from melted and solidified solder material on the multiple terminals obtained by exposing a section of each of the multiple leads from the rear surface of the package and made to protrude out farther than the rear side of the package.

(5) A semiconductor device according to the Example (4), wherein
when the solder layer height is set as a, and a solder layer width is set as b, a solder layer attains an arc shape of a/b≦½.

Typical effects obtained from the present invention as disclosed in this specification will be briefly described as follows.

The present invention renders the effect of suppressing solder peel defects on a semiconductor device that occur during surface mounting.

### BRIEF DESCRIPTION OF THE DRAWINGS

FIG. 1 is a diagrammatic top plan view showing the external structure of a semiconductor device representing a first embodiment of the present invention;

FIG. 2 is a diagrammatic bottom view showing the external structure of the semiconductor device of the first embodiment of the present invention;

FIG. 3 is an enlarged view of a portion of FIG. 2;

FIG. 4 is a diagram showing the internal structure of the semiconductor device (plan view of the state with the upper section of the package removed) of the first embodiment of the present invention;

FIG. 5 is a diagram showing the internal structure of the semiconductor device (plan view of the state with the lower section of the package removed) of the first embodiment of the present invention;

FIG. 6(a) is a cross-sectional view taken along line a-a of FIG. 4, and FIG. 6B is a cross-sectional view taken along line b-b of FIG. 4;

FIG. 7 is an enlarged view of a portion of FIG. 6(a);

FIG. 8 is a diagrammatic plan view of the lead frame used in the structure of the semiconductor device of the first embodiment of the present invention;

FIG. 9 is an enlarged view of a portion of FIG. 8;

FIGS. 10(a) and 10(b) are cross sectional views of steps in the semiconductor device manufacturing process of the first embodiment of the invention, in which FIG. 10(a) shows the chip mounting process, and FIG. 10B shows the wire bonding process in the semiconductor device manufacturing process;

FIGS. 11(a) and 11(b) are cross sectional views of steps in the molding process of the semiconductor manufacturing process of the first embodiment of the invention, in which FIG. 11(a) shows the entire lead frame positioned in the mold in the molding process, and FIG. 11(b) shows an enlarged view of a portion of FIG. 11(a);

FIGS. 12(a) and 12(b) show steps in the semiconductor manufacturing process, in which FIG. 12(a) is a diagrammatic plan view, and FIG. 12(b) is a cross sectional view of a portion of FIG. 12(a);

FIGS. 13(a) and 13(b) are cross-sectional views showing steps in the process for forming the solder layer during manufacture of the semiconductor device of the first embodiment of the invention;

FIGS. 14(a) and 14(b) are cross-sectional views showing steps in the solder layer forming process following the steps shown in FIGS. 13(a) and (b);

FIGS. 15(a) and 15(b) are cross-sectional views showing steps in the solder layer forming process following the steps shown in FIGS. 14(a) and 14(b);

FIG. 16 is a cross sectional view showing a step in the segment forming process in the manufacture of the semiconductor device of the first embodiment of the present invention;

FIGS. 17(a) to 17(c) are cross-sectional views showing steps in the semiconductor device mounting process of the first embodiment of the present invention;

FIG. 18 is a graph showing the relation of solder peeling defects (product yield during mounting) to the solder layer height;

FIG. 19 is a cross sectional view showing a fragment of an adaptation of the semiconductor device of the first embodiment of the present invention;

FIG. 20 is a cross sectional view showing the lead frame while positioned in the metal mold in the manufacture of the semiconductor device of the first embodiment of the present invention;

FIGS. 21(a) and 21(b) are cross-sectional views showing steps in the solder layer forming process during manufacture of the semiconductor device of a second embodiment of the present invention;

FIG. 22 is a cross sectional view showing a step in the segment forming process in the manufacture of the semiconductor device of the second embodiment of the present invention;

FIG. 23 is a bottom view showing the external structure of the semiconductor device of a third embodiment of the present invention;

FIG. 24(a) is a plan view and FIG. 24(b) is a structural view taken along line C-C in FIG. 24(a), showing the internal structure of the semiconductor device of the third embodiment of the present invention;

FIG. 25 is an enlarged cross sectional view showing a portion of FIG. 24(b).

The present invention renders the effect of improving the semiconductor mounting device productivity.

### DETAILED DESCRIPTION OF THE INVENTION

Various embodiments of the present invention will be described with reference to the accompanying drawings. In all of the drawings, elements having identical functions are assigned the same reference numerals, and a redundant description of those elements is omitted.

### First Embodiment

A first embodiment of the present invention will be described using, as an example, a QFN semiconductor device, which is one type of non-lead semiconductor device in which a section of the leads are exposed from the rear surface of the package and are utilized as external terminals.

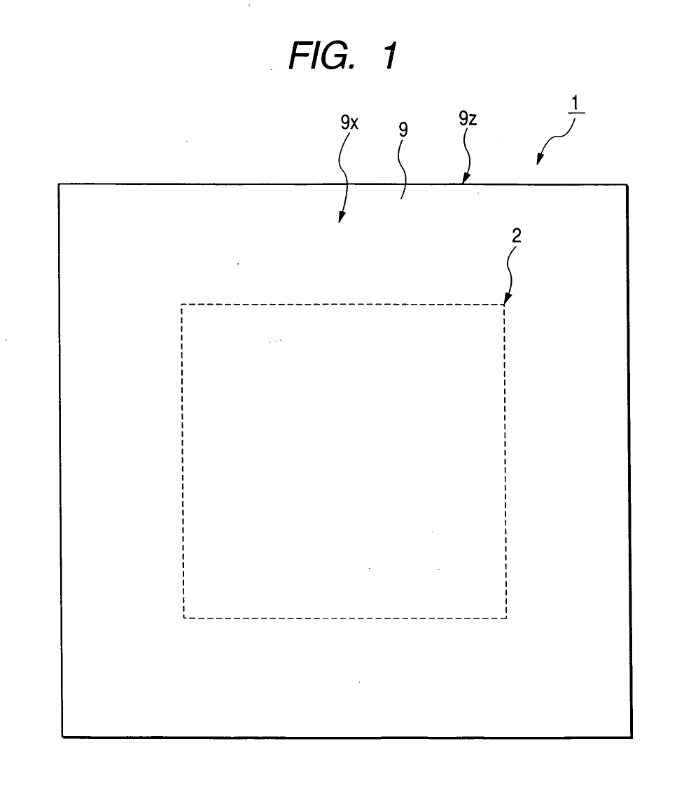

FIG. 1 through FIG. 17 are drawings of a QFN semiconductor device representing the first embodiment of the present invention.

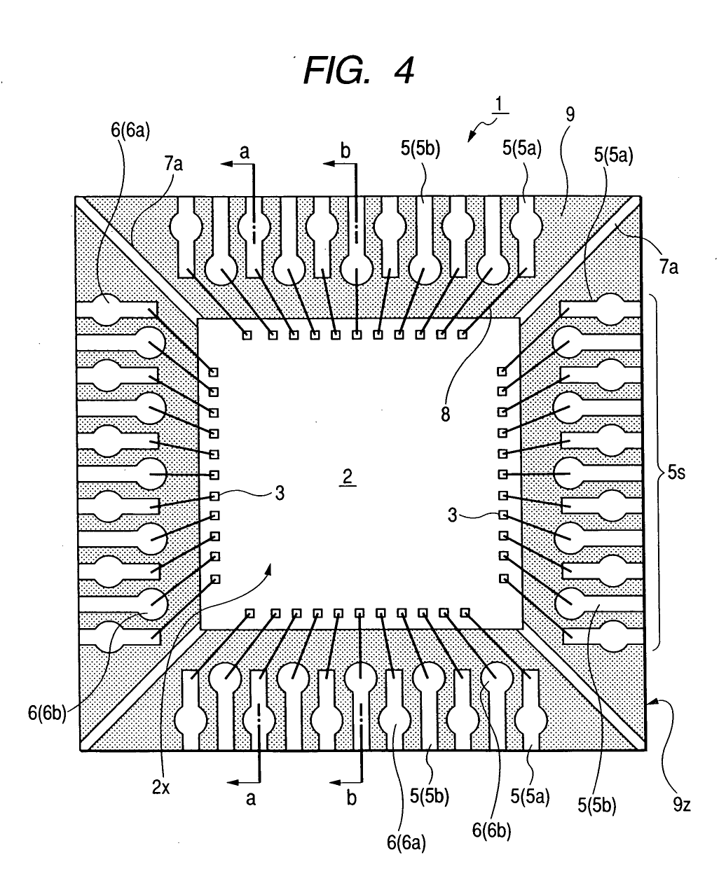

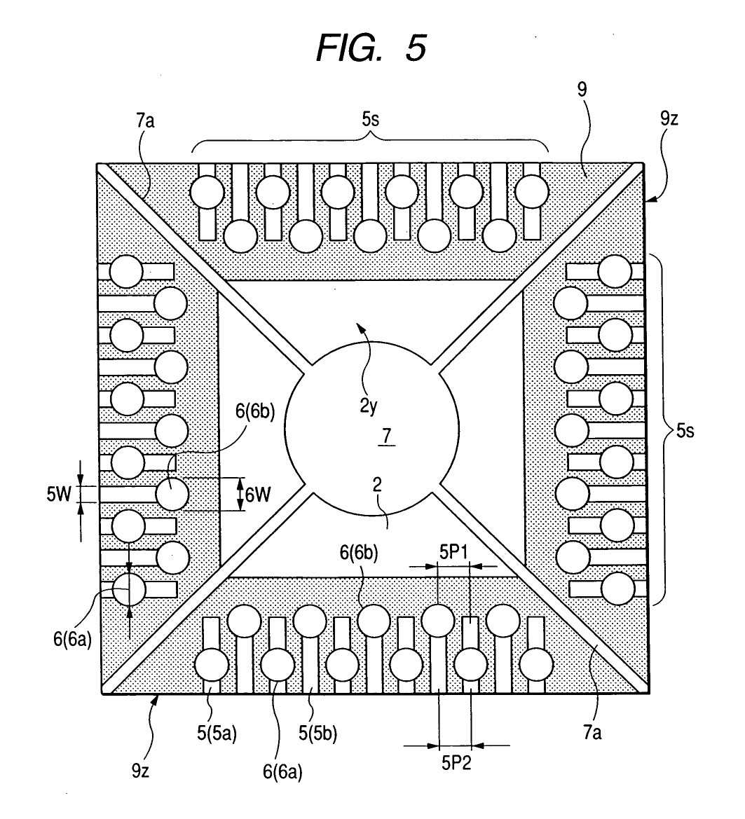

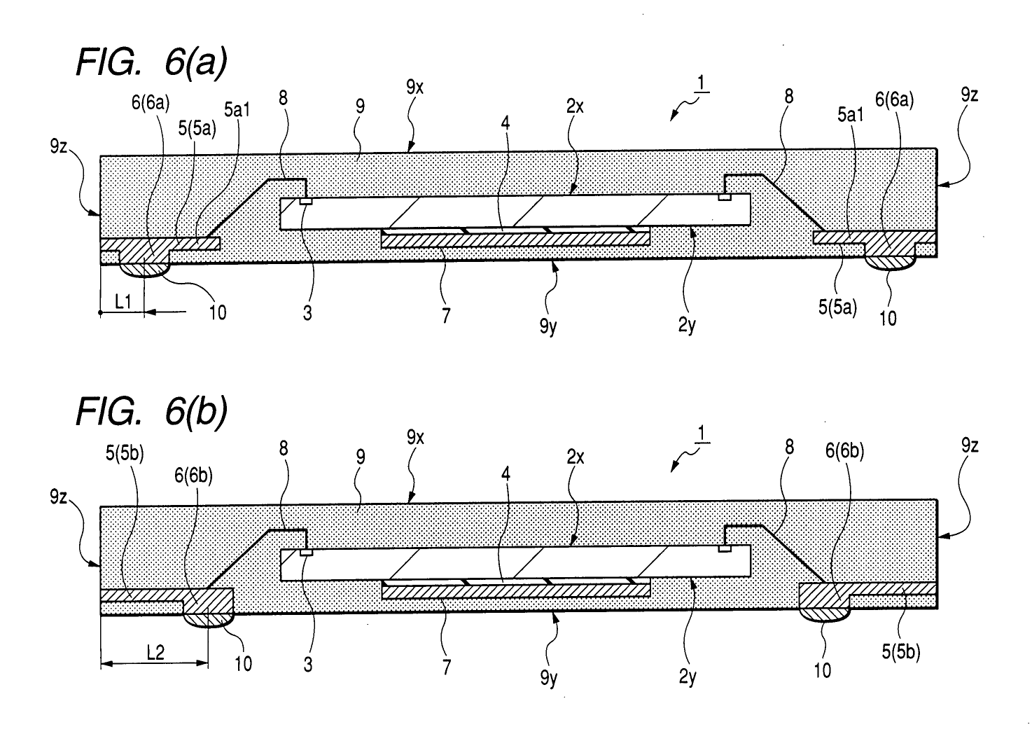

As shown in FIG. 4, FIG. 5, and FIGS. 6(a), 6(b), the QFN semiconductor device, representing as the first embodiment, has a package structure including a semiconductor chip 2, first through fourth lead groups 5s made up of multiple leads 5, chip support pieces (diepads, tabs, chip mounting section) 7, four suspension leads 7a, multiple bonding wires 8, and a plastic casing 9, etc. The semiconductor chip 2, the first through the fourth lead groups 5s made up of multiple leads 5, the chip support pieces (diepads, tabs) 7, the four suspension leads 7a and the multiple bonding wires 8 are sealed by the plastic casing 9. The semiconductor chip 2 is bonded via the adhesive member on the main surface (upper surface) of the chip support piece 7. The chip support piece 7 is formed as one integrated piece with the suspension leads 7a.

The semiconductor chip 2 is formed as a square in a flat shape intersecting in the thickness direction as shown in FIG. 4 and FIG. 5. In the present embodiment, for example, the semiconductor chip 2 has a square shape. The semiconductor chip 2 is not limited to this structure and may, for example, be formed of multiple transistors formed on the main surface of this semiconductor substrate, an insulation layer on the main surface of this semiconductor substrate, a multilayer wiring layer formed of multiple wiring layer laminations, and a surface protective film (final protective film) formed so as to cover the multi-wiring layer. The insulation layer may be formed, for example, from a silicon oxide film. The wiring layer may be formed from a metal film, such as aluminum (Al), or aluminum alloy, or copper (Cu), or copper alloy, etc. The surface protective film is formed, for example, from a multilayer film formed in laminated layers of an organic insulating film or an inorganic insulating film, such as a silicon oxide film, or a silicon nitride film, etc.

As shown in FIG. 4, FIG. 5, and FIGS. 6(a) and 6(b), the semiconductor chip 2 is made up of a main surface (device mounting surface, circuit forming surface) 2x and a rear surface 2y positioned on mutually opposite sides. The integrated circuit is formed on the main surface 2x side of the semiconductor chip 2. The integrated circuit is mainly formed of transistor devices (components) formed on the main surface of the semiconductor substrate and wiring formed on a multi-wiring layer.

As shown in FIG. 4 and FIGS. 6(a) and 6(b), multiple bonding pads (electrodes) 3 are formed on the main surface 2x of the semiconductor chip 2. These multiple bonding pads 3 are positioned along each side of the semiconductor chip 2. The multiple bonding pads 3 are formed on the topmost wiring layer of the multi-wiring layers of the semiconductor chip 2. Each of the bonding pads 3 is exposed by a corresponding bonding opening formed on the surface protective layer of the semiconductor chip 2.

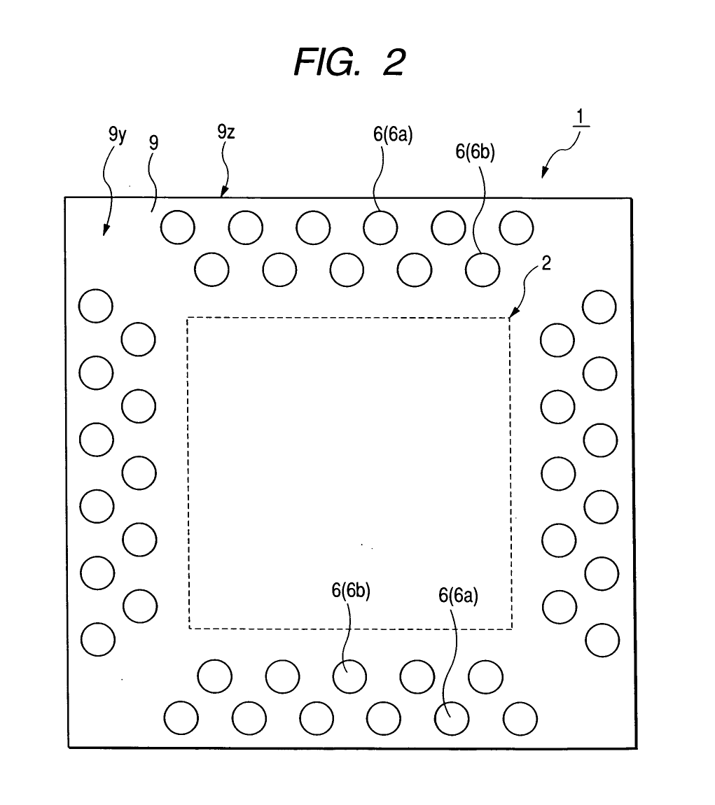

The plastic casing 9 is formed in a flat shape with the flat plane intersected in the thickness direction as shown in FIG. 1 and FIG. 2. In the present embodiment, the plastic casing 9 is a square in shape. The plastic casing 9 includes a main surface (upper surface) 9x and a rear surface (lower surface, mounting surface) 9y on opposite sides as shown in FIG. 1, FIG. 2 and FIGS. 6(a) and 6(b). The flat plane size (contour size) of the plastic casing 9 is larger than the flat plane size of the semiconductor chip 2.

The plastic casing 9 is formed from a phenol type thermosetting resin with, for example, a phenol type hardener, silicon rubber and a filler in order to provide a low stress package. The transfer molding method suitable for mass production is the method utilized for forming the plastic casing 9. The transfer molding method utilizes a forming mold (metal mold) formed of a port, runner, resin injection gate and cavity, etc. In the transfer molding method, a thermosetting resin is injected inside the cavity from the port via the resin injection gate and runner.

The semiconductor device package is manufactured using single type or batch type transfer molding. The single type transfer molding method seals individual semiconductor chips (mounted in the product forming region) inside the product forming region by utilizing a lead frame (multi-element lead frame) including multiple product forming regions (device forming region, product acquisition region). The batch type transfer molding method seals a batch of semiconductor chips mounted in the product forming region by utilizing a lead frame containing multiple product forming regions. The first embodiment, for example, uses the batch type transfer molding method.

In the batch type transfer molding method, after forming the package, the lead frame and the package are separated into multiple segments, for example, by dicing. Therefore, in the first embodiment, the main surface 9x and the rear side 9y and their contour (outer dimensional) size are approximately the same in the plastic casing 9. The side surface 9z of the plastic casing 9 is mainly perpendicular to the main surface 9x and rear surface 9y.

As shown in FIG. 4 and FIG. 5, the first through fourth lead groups 5s are positioned to correspond to each of the four sides of the plastic casing 9. The multiple leads 5 of each lead group 5s are arrayed in the same direction as the sides (the sides of plastic casing 9) of the semiconductor chip 2. Also, the multiple leads 5 of each lead group 5s extend towards the semiconductor chip 2 from the side 9z of the plastic casing 9.

The multiple bonding pads 3 of the semiconductor chip 2 are each electrically connected with the multiple leads 5 of the first through fourth lead groups 5s. In the first embodiment, the bonding wire 8 makes an electrical connection between the lead 5 and the bonding pad 3 of the semiconductor chip 2. One end of the bonding wire 8 is connected to the bonding pad 3 of the semiconductor chip 2. The other end, on the opposite side of the bonding wire 8 and the terminal, is connected to the lead 5 on the external side (periphery) of the semiconductor chip 2. The bonding wire 8 may, for example, be a gold (Au) wire. The method for connecting the bonding wire 8 may utilize the nail head bonding (ball bonding) method that jointly employs ultrasonic oscillation along with heat crimping.

Each of the multiple leads 5 of the lead groups 5s contains multiple leads 5a and multiple leads 5b, as shown in FIG. 4, FIG. 5 and FIGS. 6(a) and 6(b). The leads 5a contain a terminal 6a on the side surface 9z of the plastic casing 9 (vicinity of side surface 9z of the plastic casing 9). The leads 5b contain a terminal 6b that is located farther inside (semiconductor chip 2 side) than the terminal 6a. In other words, the terminals 6b of the leads 5b are formed at a position farther away from the (edge) side surface 9z of the plastic casing 9 than the terminal 6a of the lead 5a.

The terminals (6a, 6b) 6 are integrated into one piece with the leads (5a, 5b) 5, as shown in FIGS. 6(a) and 6(b). The thickness of the other portions of the leads 5 are thinner than the terminal 6, with the exception of the terminal 6 (terminal 6 thickness>thickness of other sections). Also, as shown in FIG. 5, the width 6W of the terminals (6a, 6b) 6 is wider than the width 5W on the section on one end of the lead 5 (side near the semiconductor chip 2) and the other end on the opposite side (side near the side surface 9z of the plastic casing 9).

As shown in FIG. 4 and FIG. 5, the multiple leads 5 of each lead group 5s are configured in positions so that the leads 5a and leads 5b alternately repeat (along the side of semiconductor chip 2, or along the same direction of the side of the plastic casing 9) in one direction, with the leads 5a and leads 5b being mutually adjacent to one another.

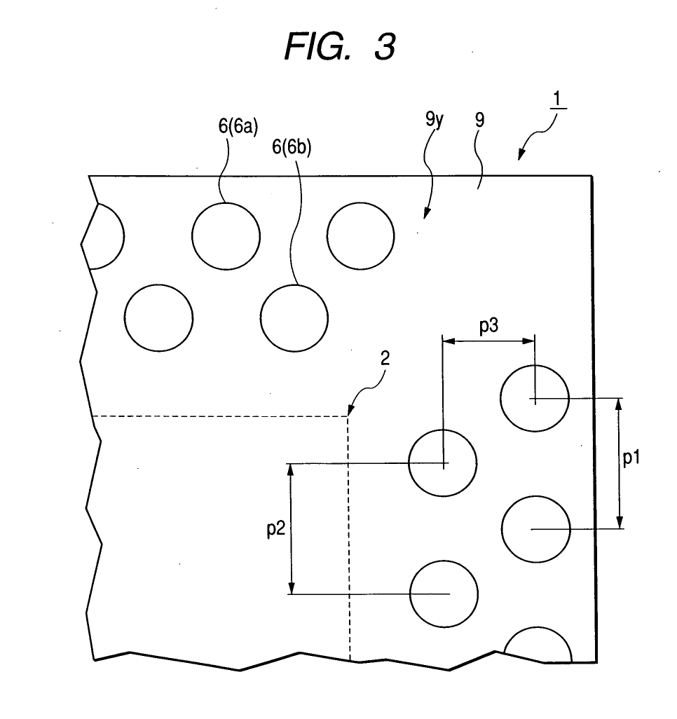

As shown in FIG. 2 and FIG. 3, and FIGS. 6(a), 6(b), the terminals (6a, 6b) 6 of the leads (5a, 5b) 5 are exposed from the rear surface 9y of the plastic casing 9, and they are utilized as external terminals. A solder layer 10 is formed on the tip of the terminal 6 (section exposed from the rear surface 9y of the plastic casing 9). The semiconductor device 1 of the first embodiment is mounted by soldering these terminals (6a, 6b) 6 to the electrode pads (footprint, lands, connecting sections) of the printed circuit board.

Each of the terminals 6 of the multiple leads 5 on the lead groups 5s are arrayed in two rows in a zigzag pattern along the sides of the plastic casing 9, as shown in FIG. 2 through FIG. 5. The first row of terminals nearest the side of the plastic casing 9 is made up of the terminals 6a. The second row of terminals positioned further inwards than the first row is made up of the terminals 6b. The array pitch P1 of the first row of terminals 6a and the array pitch P2 (see FIG. 3) of the second row of terminals 6b are wider than the array pitch 5P2 (see FIG. 5) on the end of the other side of the leads 5.

In the first embodiment, the array pitch P2 of terminal 6b and the array pitch P1 of the terminal 6a are, for example, approximately 650 [μm]. The array pitch 5P2 on the end on the other side of the leads 5 is, for example, approximately 650 [μm].

The width 6W of the terminals (6a, 6b) 6 (see FIG. 5) is for example approximately 300 [μm]. The width 5W of the terminals (5a, 5b) 5 (see FIG. 5) is for example approximately 200 [μm].

The distance L1 of the terminal 6a, which is the amount separating the side surface 9z (edge) of plastic casing 9 (see FIG. 6) from the inner side (semiconductor chip 2 side), is, for example, approximately 250 [μm]. The distance L2 of the terminal 6b, which is the amount separating the side surface 9z (periphery) of plastic casing 9 (see FIG. 6) from the inner side (semiconductor chip 2 side), is, for example, approximately 560 [μm].

The thickness of the terminals (6a, 6b) 6 is, for example, approximately 125 [μm] to 150 [μm]. The thickness of the other sections of lead 5, except for terminal 6, is, for example, approximately 65 [μm] to [75] μm (see FIGS. 6(a), 6(b).

The semiconductor device 1 of the first embodiment, as described above, includes a lead 5a, which is exposed from the rear surface 9y of the plastic casing 9 and is formed with a terminal 6a that is utilized as an external terminal, and a lead 5b, which is exposed from the rear surface 9y of the plastic casing 9 and is formed with a terminal 6b that is utilized as an external terminal, and is positioned farther to the inside than the terminal 6a; and, the leads 5a and the leads 5b are formed adjacent to each other and at alternate repeating positions along the same direction (sides of the plastic casing 9) as the side of the semiconductor chip 21.

The width 6W of the terminals (6a, 6b) 6 is wider than the width 5W on the section on one end of the lead (5a, 5b) 5 on the end on the other side.

By utilizing a package structure of this type, the surface area required for maintaining reliability during mounting can be secured for the terminals (6a, 6b) 6 even if the leads (5a, 5b) 5 have been made tiny, and, therefore, many pins can be used in the package without having to change the package size.

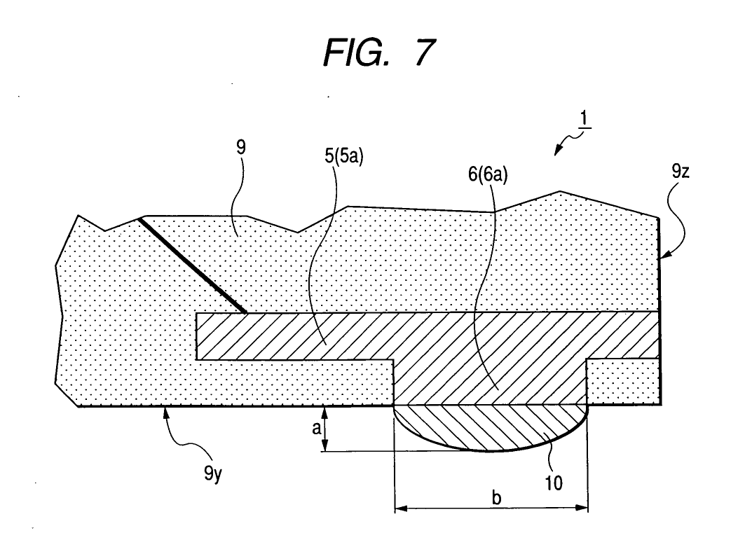

As shown in FIG. 4 and FIGS. 7(a), 7(b), the multiple leads (5a, 5b) 5 extend from the side surface 9z of the plastic casing 9 straight towards the semiconductor chip 2. Each end of the leads 5 terminates on the outer side of the semiconductor chip 2, and each of the other ends terminates on the side surface 9z of the plastic casing 9. In the first embodiment, the lead 5a includes a section (extended section) 5a1 (See FIG. 6A) extending from that terminal 6a towards the semiconductor chip 2. One end of the lead 5a terminates farther inside (semiconductor chip 2 side) than the terminal 6a. One end of the lead 5b terminates on that terminal 6b. The multiple leads 5 are formed in a pattern that is approximately the same as the array pitch 5P1 at one termination end (See FIG. 5) and the array pitch 5P2 (See FIG. 5) on the other termination end.

As shown in FIG. 5 and FIGS. 6(a), 6(b), the flat surface (plane) size of the chip support piece 7 is smaller than the flat surface size of the semiconductor chip 2. In other words, the flat surface size of the chip support piece 7 is formed in a so-called small tab structure, smaller than the flat surface size of the semiconductor chip 2 in the semiconductor device 1 of the first embodiment. This small tab structure can be mounted on a number of types of semiconductor chips of different flat surface sizes so that the productivity is streamlined and the production costs are lower. The thickness of the chip support piece 7 is thinner than the terminal 6 lead 5 thickness. Except for the terminal 6, the thickness of the chip support piece 7 is approximately the same as the other sections of the lead 5.

The solder layer 10 protrudes outward from the rear surface 9y of the plastic casing 9, as shown in FIG. 7. When the height of the solder layer 10 is set as a, and the width b of the solder layer 10 is set as b, the solder layer has an arc shape of a/b≦½. This arc-shaped solder layer 10 can easily be formed to solidify the molten solder. Methods for forming the solder layer 10 will be explained in detail later on, but they include a method for melting the solder paste material formed on the terminal 6 and a method (solder dip method) for depositing melted solder material onto the terminal 6.

The thickness of the arc-shaped solder layer 10 gradually becomes thinner from the center of the solder 10 towards the periphery. This fact also signifies that the center of the solder layer 10 is thicker than it is at the periphery.

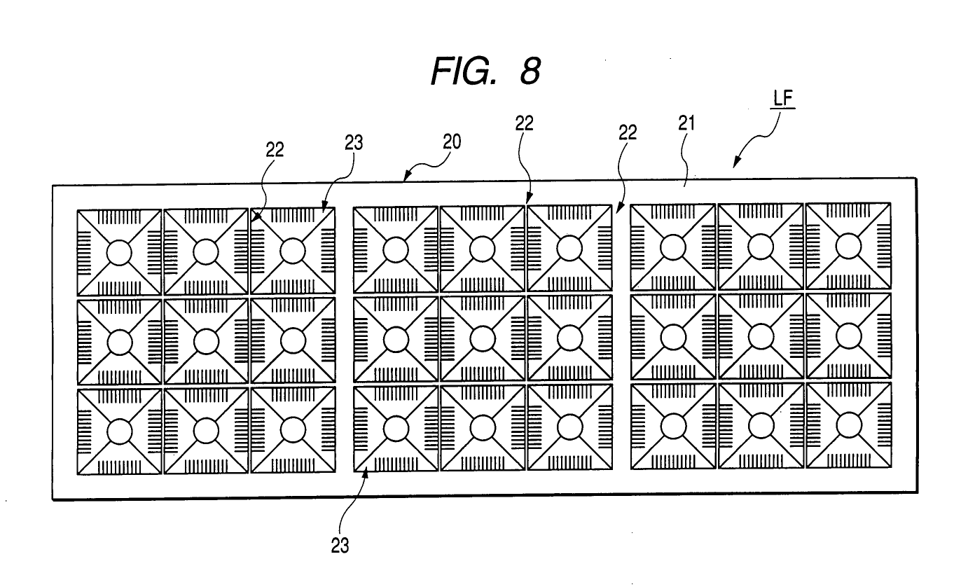

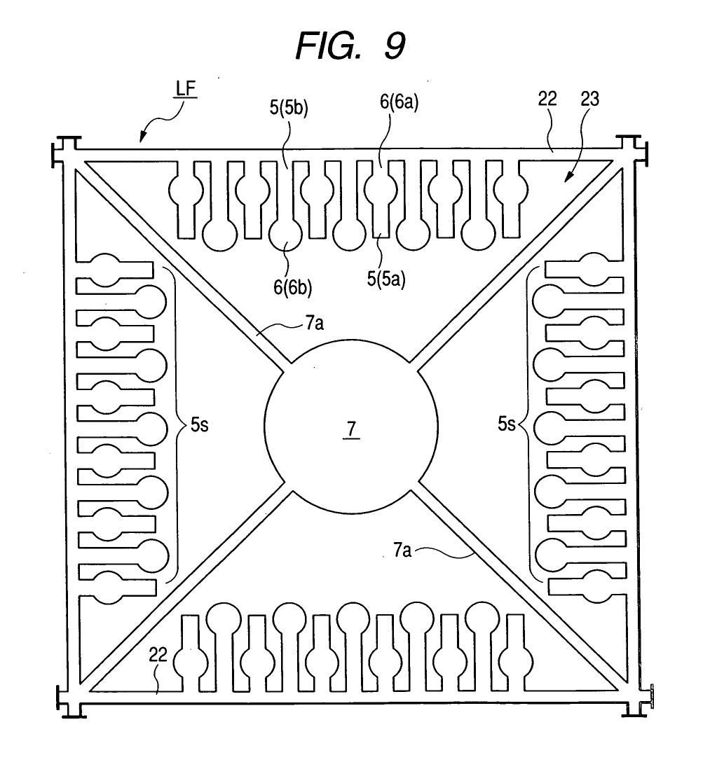

The lead frame utilized in the manufacture of the semiconductor device 1 will be described next with reference to FIG. 8 and FIG. 9.

The lead frame LF, as shown in FIG. 8, for example, contains multiple product forming regions (device forming regions, product acquisition regions) 23 segmented into frame units (support pieces) 20 containing external frames 21 and internal frames 22 in a continuous structure in the form of a matrix. First through fourth lead groups 5s, made up of multiple leads 5, are formed in the product forming region 23, as shown in FIG. 9. The flat surface shapes of the product forming region 23 have a square shape. The first through fourth lead groups 5s are formed in four sections corresponding to the frame unit 20 enclosing the product forming regions 23. The multiple leads 5 of the lead groups 5s include the multiple leads 5a and 5b. The leads 5a and the leads 5b are mutually formed repetitively in one direction so as to be mutually adjacent. The multiple leads 5 of the lead groups 5s are also linked to corresponding sections (external frames 21 and internal frames 22) on the frame unit 20. The multiple leads 5 of the lead groups 5s also are easily bondable with the bonding wire, so that a plating layer, for example, of palladium (Pd), can be connected to each bonding wire.

To manufacture the lead frame LF, a metal plate made from copper (Cu), or copper alloy, or an alloy of iron (Fe) and nickel (Ni) and having a thickness of 125 [μm] to 150 [μm] is first prepared. One surface of the sections forming the leads 5 is covered with a photoresist film. The sections forming the terminal 6 are covered on both sides with a photoresist film. The metal is then etched by a chemical while in this state. The thickness of the metal plate on one side covered with the photoresist film is thinned, for example, by about half (65 [μm] to 75 [μm] (half etching). By performing the etching using this method, the metal plate on the regions on both sides not covered with the photoresist film are completely stripped away. The leads 5 are formed to a thickness of approximately 65 [μm] to 75 [μm] on one side on a region covered with the photoresist. The regions on the metal plate on both sides that are covered with the photoresist film are not stripped (or etched) away by a chemical, so that a pointed terminal 6 having a thickness of 125 [μm] to 150 [μm], which is identical to the pre-etching thickness, is obtained. The lead frame LF is next completely formed by removing the photoresist film, as shown in FIG. 8 and FIG. 9.

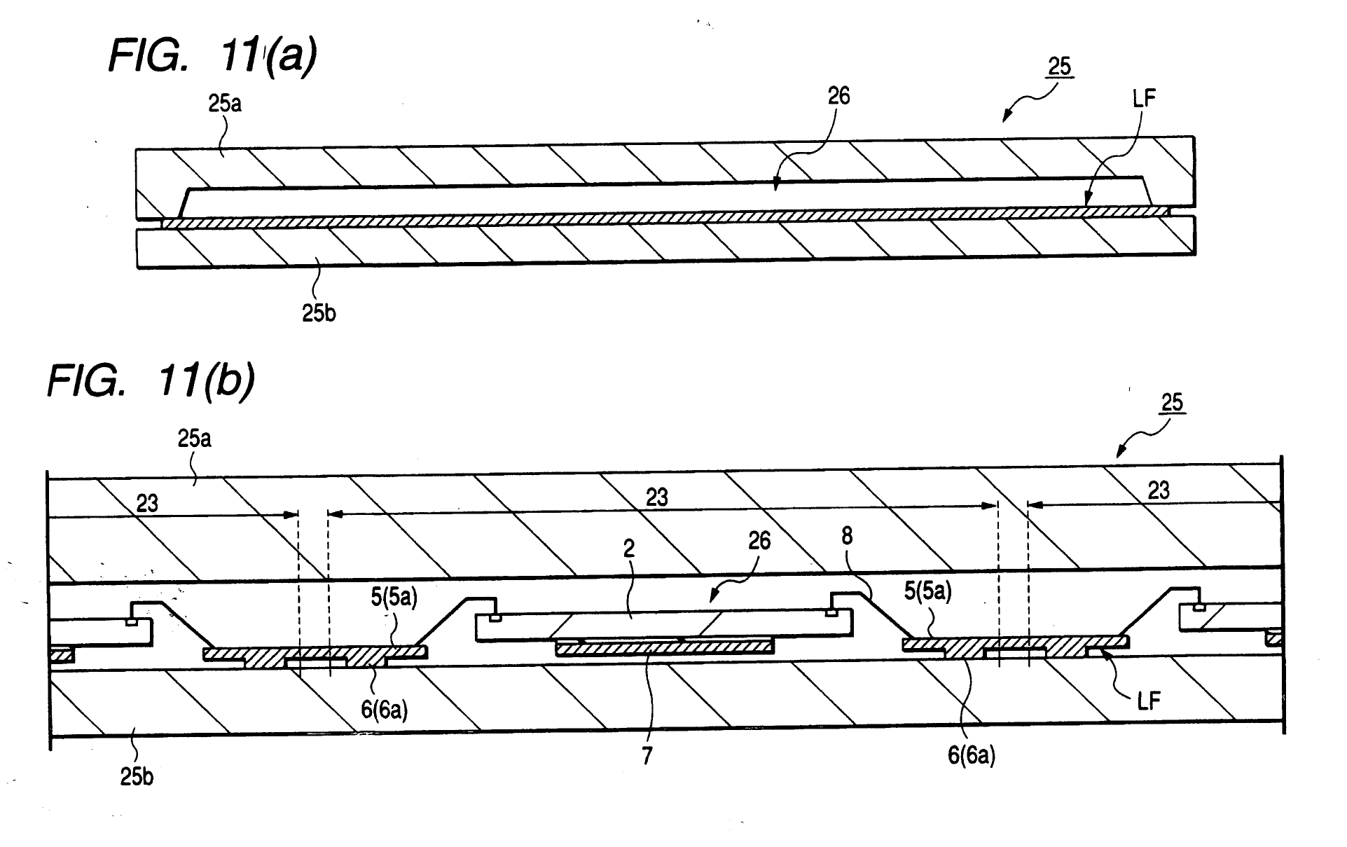

The forming metal mold used in manufacturing the semiconductor device 1 will be described next with reference to FIGS. 11(a) and 11(b).

The shape of the metal mold 25 is shown in FIGS. 11(a) and 11(b). Though not limited to this shape, the metal mold 25 includes an upper mold 25a and a lower mold 25b, separated above and below. The metal mold 25 further includes a port, cull, runner, resin injection gate, cavity 26 and air vent, etc. The metal mold 25 further contains a lead frame LF positioned between the alignment surface of the upper mold 25a and the alignment surface of the lower mold 25b. The cavity 26 of the metal mold 25 in formed of the upper mold 25a and the lower mold 25b when resin is injected in the cavity 26, and the mating surface of the upper mold 25a and the lower mold 25b are aligned with each other. In the first embodiment, the cavity 26 of the metal mold 25 is not limited to the shape shown here. The cavity 26 may, for example, be formed by a concavity formed in the upper mold 25a and the lower mold 25b. The cavity 26 has a flat surface size capable of storing the multiple product forming regions 23 of the lead frame LF altogether.

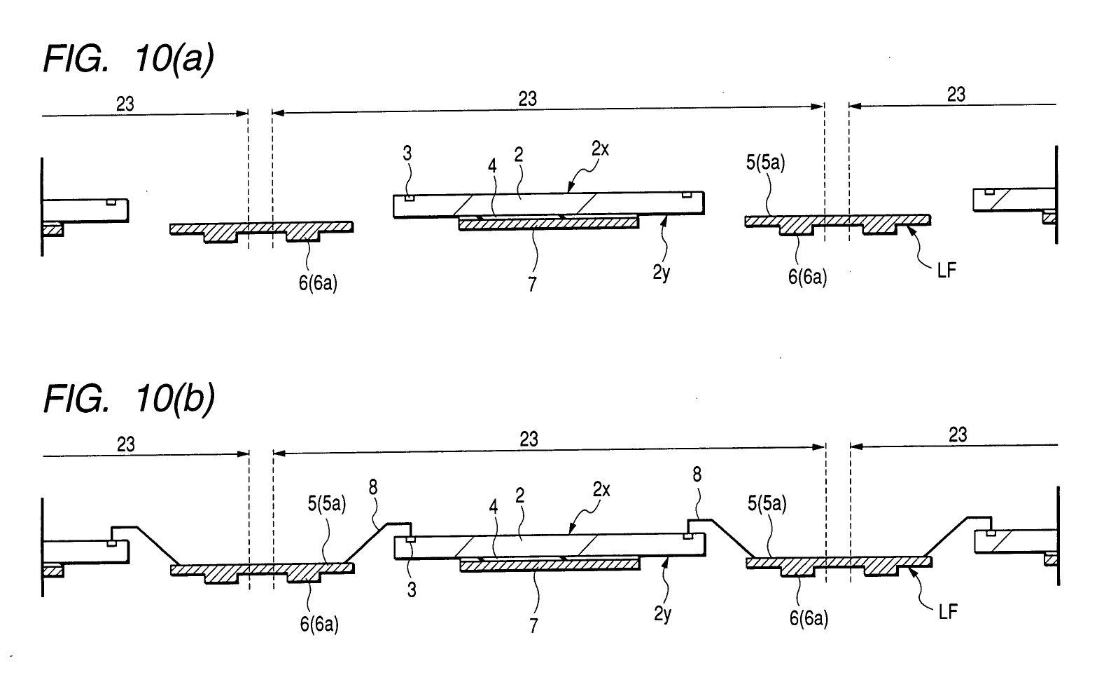

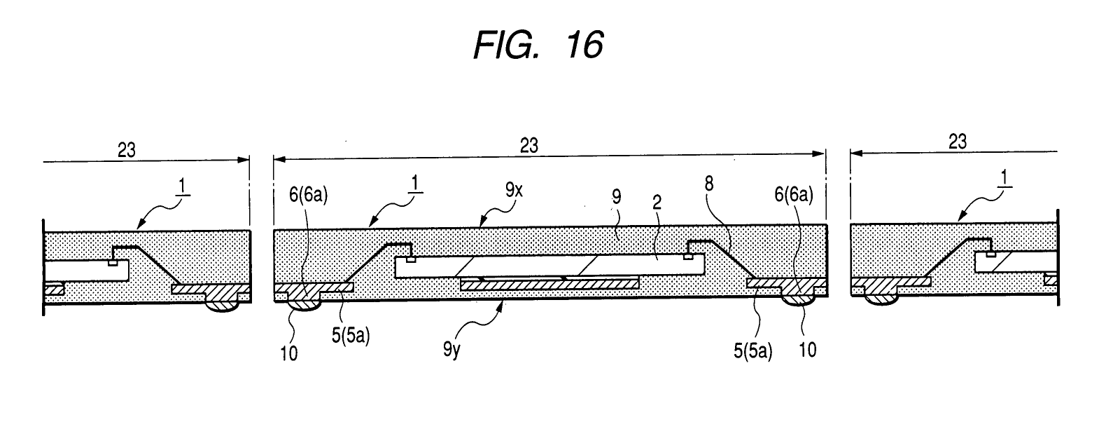

The manufacture of the semiconductor device 1 will be described next with reference to FIGS. 10(a), 10(b) and FIG. 16.

The lead frame LF, first of all, is prepared as shown in FIG. 8 and FIG. 9. In each product forming region 23, the semiconductor chip 2 is then adhered to the chip support piece 7 of the lead frame LF using the adhesive member 4. The semiconductor chip 2 is adhered (clamped) in a state where the main surface of the chip support piece 7 and the rear surface 2y of the semiconductor chip 2 are facing each other.

Next, as shown in FIG. 10(b), the multiple bonding pads 3, positioned on the main surface 2x of the semiconductor chip 2, are each electrically connected with the multiple leads (5a, 5b) 5 by the multiple bonding wires 8 in the product forming region 23.

Next, as shown in FIG. 11(a) and FIG. 11(b), the lead frame LF is positioned between the upper mold 25a and lower mold 25b of the metal mold 25.

The positioning of the lead frame LF is carried out in a state where multiple product forming regions 23 are positioned inside one cavity 26. In other words, the positioning of the lead frame LF is carried out in a state where the semiconductor chip 2, lead 5 and bonding wire 8 of the product forming region 23 are positioned inside one cavity 26.

The positioning of the lead frame LF is carried out in a state where the terminals 6 of the lead 5 are in contact with the inner surface of the cavity 26 facing these terminals 6.

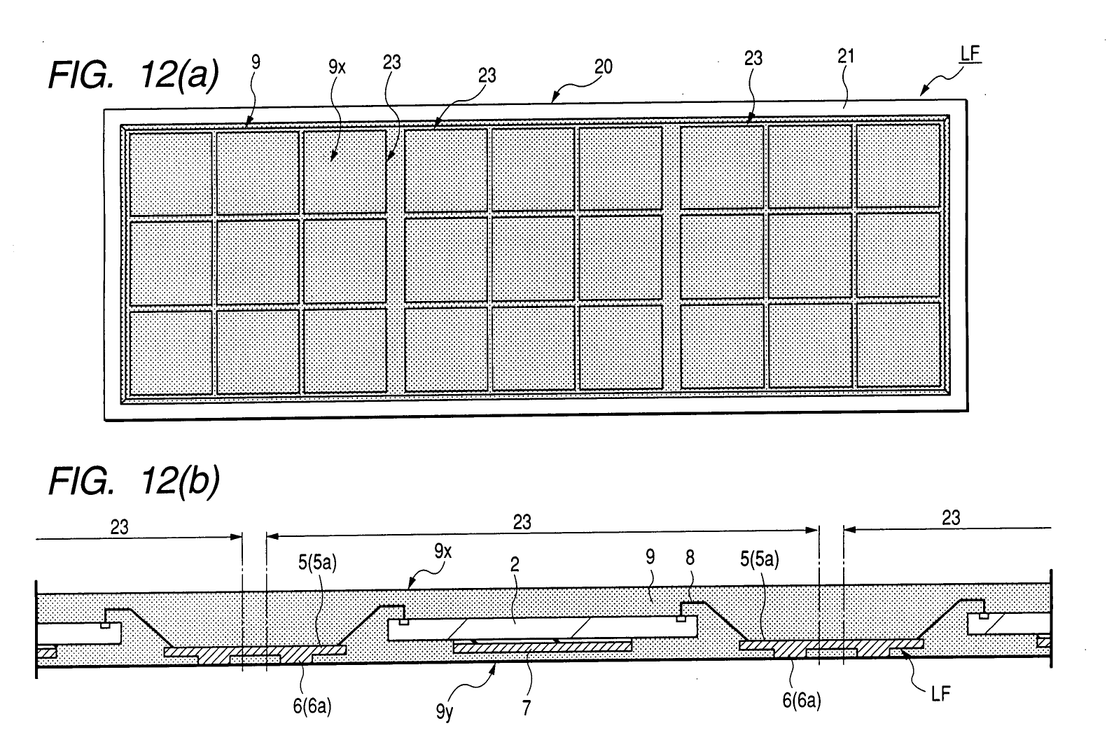

Next, with the lead frame LF positioned as described above, a thermosetting resin is injected, for example, inside the cavity 26 from the port of the metal mold 25 by way of the cull, runner and resin injection gate to form the plastic casing 9, as shown in FIG. 12(a) and FIG. 12(b). The semiconductor chip 2, the multiple leads 5, and the multiple bonding wires 8 in the product forming area 23 are all sealed together in one plastic casing 9. The multiple terminals 6 of each product forming area 23 are exposed from the rear surface 9y of the plastic casing 9.

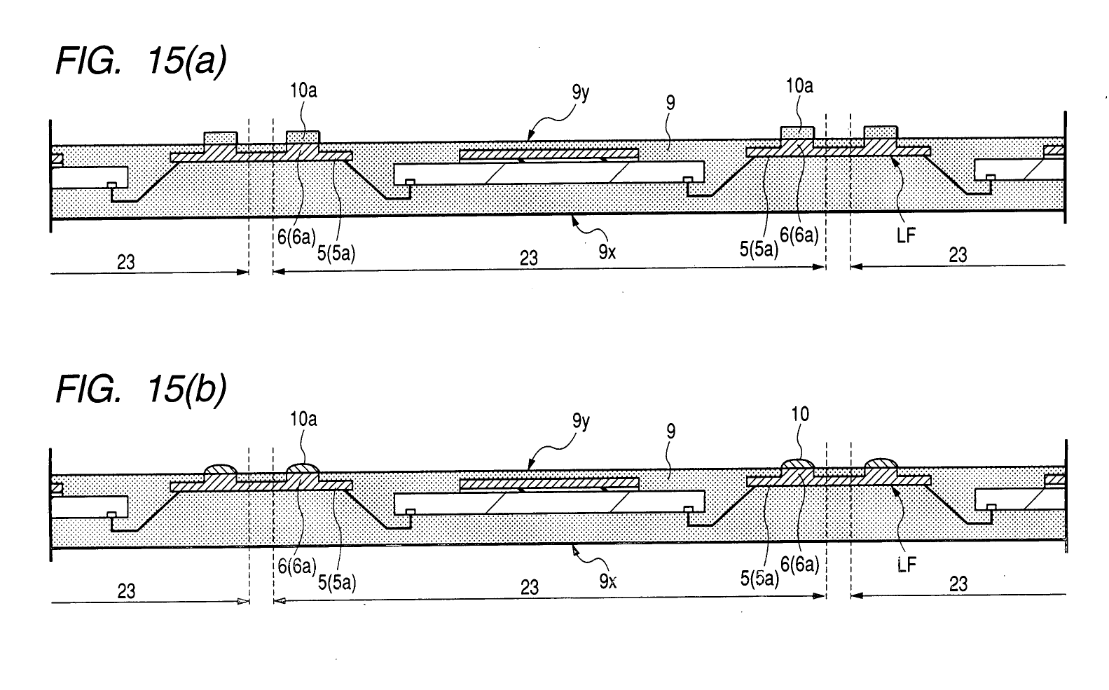

Note, the lead frame LF is extracted from the metal mold 25. A solder layer 10 is then formed in each of the product forming regions 23 on the surface of the terminal 6 exposed from the rear surface 9y of the plastic casing 9, as shown in FIG. 15(b).

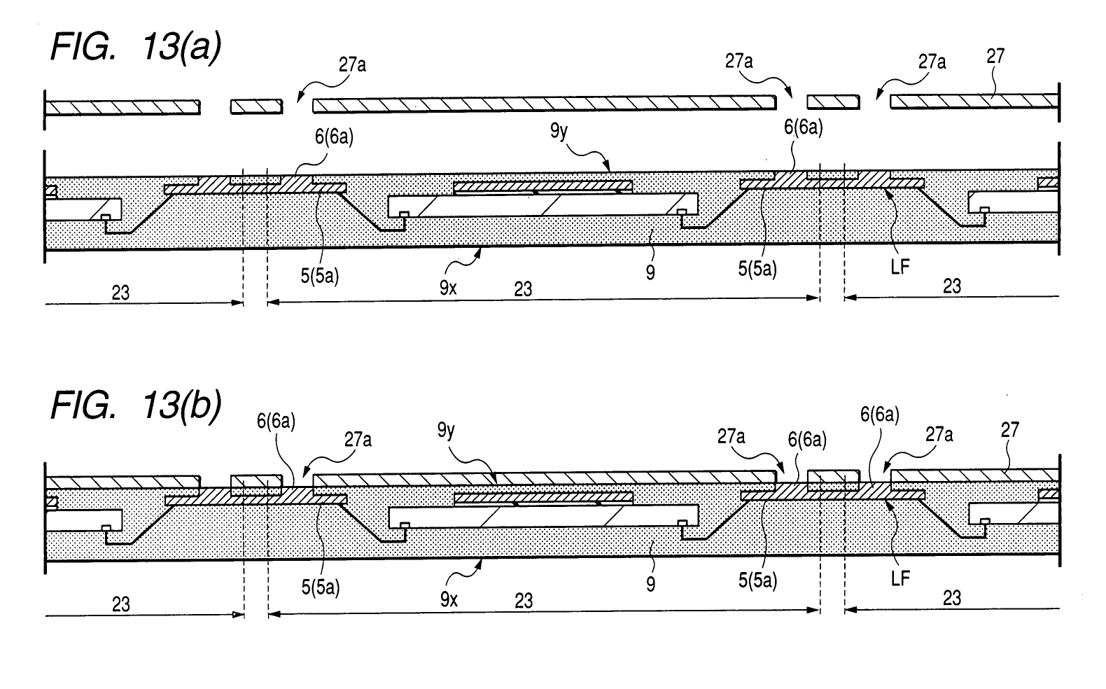

The solder layer 10 in the first embodiment is formed by the reflow soldering method utilizing, for example, screen printing technology. More specifically, a metal mask 27 for screen printing is prepared as shown in FIG. 13(a). This metal mask 27 contains multiple openings 27a. These multiple openings 27a are formed to correspond to the numerous terminals 6 exposed from the rear surface 9y of the plastic casing 9.

Each of the multiple openings 27a of the metal mask 27 is positioned over one of the terminals 6 that are exposed from the rear surface 9y of the plastic casing 9. The metal mask 27 is sealed to the rear surface 9y of the plastic casing 9 as shown in FIG. 13(b).

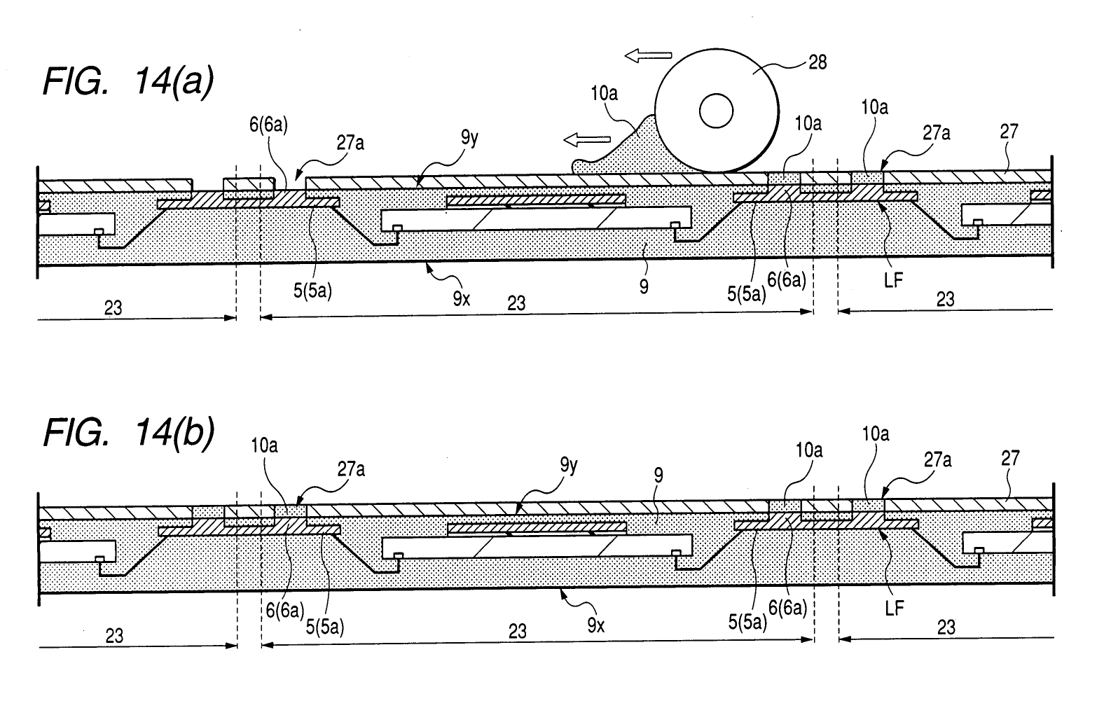

Next, the solder paste material 10a is applied to the metal mask 27. A squeegee 28 is then slid along the surface of the metal mask 27, as shown in FIG. 14(a). The solder paste material 10a is then filled into the multiple opening 27a on the metal mask 27, as shown in FIG. 14(b). The solder paste material 10a that is utilized may at least be formed, for example, of tiny solder particles mixed with flux.

As shown in FIG. 15(a), the metal mask 27 is removed from the rear surface 9y of the plastic casing 9. Afterwards, the plastic casing 9 is conveyed to an infrared reflow furnace where the solder paste material 10a is melted and later solidified. A solder layer 10 having an arc shape protruding from the rear surface 9y of the plastic casing 9 is formed, in this way, on each surface of the multiple terminals 6 that are exposed from the rear surface 9y of the plastic casing 9.

The thickness (amount of protrusion) of the solder layer 10 can be easily adjusted by changing the size of the openings 27a and the thickness of the metal mask 27.

As shown in FIG. 16, the lead frame LF and the plastic casing 9 are segmented into product forming regions 23, for example, by dicing to form the segments of the plastic casing 9. The semiconductor device of FIG. 1 through FIG. 7 is mainly formed in this way.

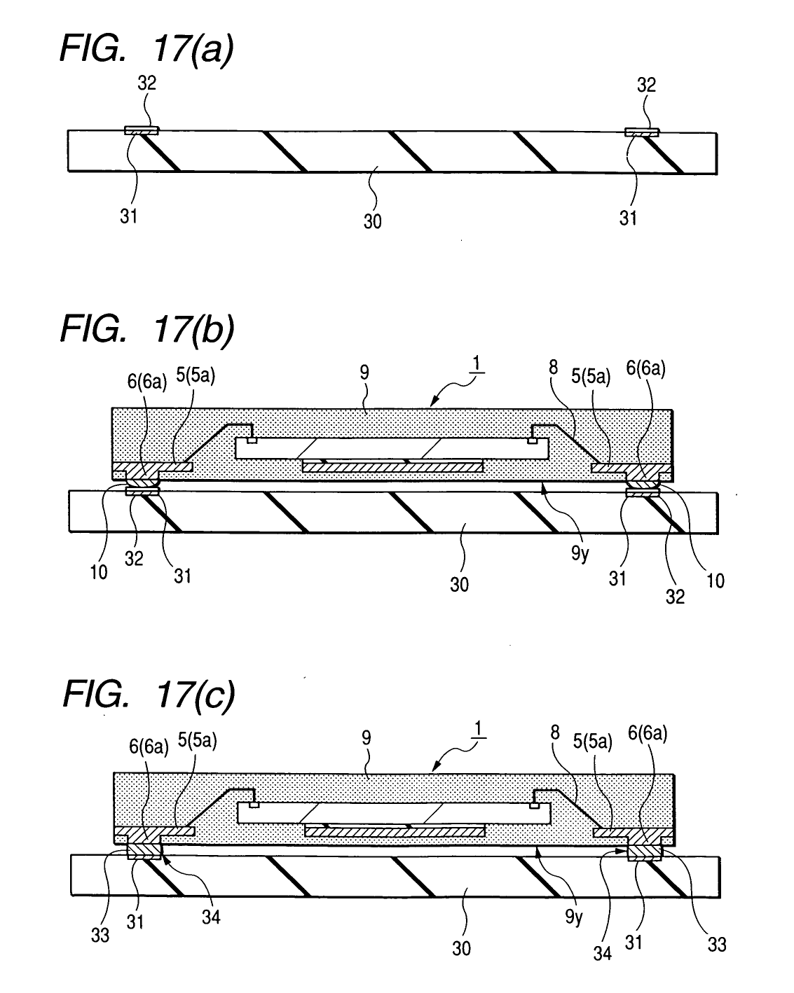

The method used for mounting the semiconductor device 1 by reflow soldering will be described with reference to FIGS. 17(a) to 17(c).

The semiconductor device 1 is first prepared as shown in FIG. 1 through FIG. 7. The printed circuit board (mounting board) 30 is then prepared as shown in FIG. 17(a). The printed circuit board 30 contains multiple electrodes (footprints, lands, connecting pads) 31 at positions corresponding to the multiple terminals 6 of the semiconductor device 1.

As shown in FIG. 17(a), a solder paste member 32 is then formed by a method such as screen printing on the electrodes 31 of the printed circuit board 30. The semiconductor device 1 is then positioned on the main surface of the circuit board 30 so that each of the multiple terminals 6 of semiconductor device 1 is positioned over the multiple electrodes 31 of the printed circuit board 30. The solder layer 10 and the solder paste 32 are then melted and later solidified. The terminals 6 on the semiconductor 1, in this way, are electrically and mechanically connected to the electrodes 31 of the printed circuit board 30 by the solder layer 33, and the semiconductor device 1 is mounted on the printed circuit board 30.

A description of the other electrical components in the first embodiment is omitted. However, the QFN semiconductor device 1 may be mounted along with the other surface-mounted electrical components on the printed circuit board. The QFN semiconductor device 1, for example, may be incorporated into compact electronic equipment, such as cellular telephones, portable information processing terminal equipment, and portable personal computers. The reflow soldering method is generally used to increase the productivity when mounting the QFN semiconductor 1 and other surface-mounted electronic components.

The QFN semiconductor 1 is exposed to high temperatures during the mounting process. These high temperatures accelerate a hardening reaction in the thermosetting resin (plastic casing 9) that seals the semiconductor chip, and causes warping on the package (plastic casing 9). This package warping generates stress in the solder joint (section where the terminal 6 of the QFN semiconductor 1 is joined via the solder layer 33 to the electrode pad 31 of the printed circuit board 30) after mounting, as shown in FIG. 17(c). This warping (and stress) is a factor in the problem (solder peeling defect) of so-called peeling of the terminal 6 of the QFN semiconductor 1 from the electrode pad 31 of the printed circuit board 30.

The package size tends to increase even in the QFN semiconductor device 1 due to the demand for a more sophisticated performance and functions that require a large number of pins. The degree of warping of the package increases during mounting as the package sizes become larger. Therefore, solder peeling defects are more prone to occur especially in large package size QFN semiconductor devices.

These solder peeling defects can be suppressed by making the solder layer 33, that is interposed between the electrode pad 31 of printed circuit board 30 and the terminal 6 of QFN semiconductor device 1, thicker (thickness of solder layer after mounting). One method to thicken the solder layer 33 after mounting is to increase the thickness of the solder paste member 32 (See FIG. 17A) during mounting. In the reflow soldering method, however, other surface-mounted components are usually mounted in one batch along with the QFN semiconductor device 1 on one printed circuit board 30. Therefore, when the solder paste member 32 has been thickened in the QFN semiconductor device 1 mounting area, the solder paste member will also be thickened for the other surface-mounted components. Phenomenon, such as the Chip Standing Phenomenon and Manhattan Phenomenon, are therefore prone to easily occur in other surface mounted components, for example, chip type electronic components, such as chip resistors and chip capacitors that tend to stand erect due to the surface tensility of the solder. Thus, suppressing solder peeling defects in a QFN semiconductor device 1 by thickening the solder paste member 32 is not desirable.

In the first embodiment of the present invention, on the other hand, the solder layer 33 that is interposed between the electrode pad 31 of printed circuit board 30 and the terminal 6 of the QFN semiconductor device 1 can be selectively thickened (solder layer thickness after mounting). This selected thickening is achieved by making the terminal 6 of the semiconductor device 1 protrude out farther than the rear surface 9y of the plastic casing 9, and also by forming the melted and solidified solder material into an arc-shaped solder layer 10. The chip standing phenomenon in the other surface-mounted components can therefore be suppressed, and solder peeling defects in the QFN semiconductor device 1 can be eliminated.

A method used for forming the solder layer 10 by plating is known in the related art. However, the thickness used in this plating method is limited to approximately 20 μm. Therefore, solder layer 10 cannot be formed to have a thickness at the terminal 6 of the QFN semiconductor device 1 (from the electrode pad 31 of the printed circuit board 30) that is required for suppressing solder peeling defects. In the first embodiment, on the other hand, the solder layer 10 is formed by melting the solder paste material by screen printing and then solidifying the solder. Moreover, the thickness of the solder layer 10 can be easily formed by changing the size of the opening 27a and the thickness of the metal mask 27 so that the problem of the terminal 6 of QFN semiconductor device 1 peeling from the electrode pad 31 of the printed circuit board 30 is eliminated.

The method used for forming the solder layer 10 to the required thickness involves the formation of a solder bump on the melted solder ball at the terminal 6. In this case, the solder layer 10 can be thickened. However, the width of the solder bump is wider than the width of the terminal 6, so that solder bridges are easily prone to occur between adjacent terminals 6 when the array pitch of the terminal 6 is narrow. The QFN semiconductor device 1 also has a high mounting height in this case.

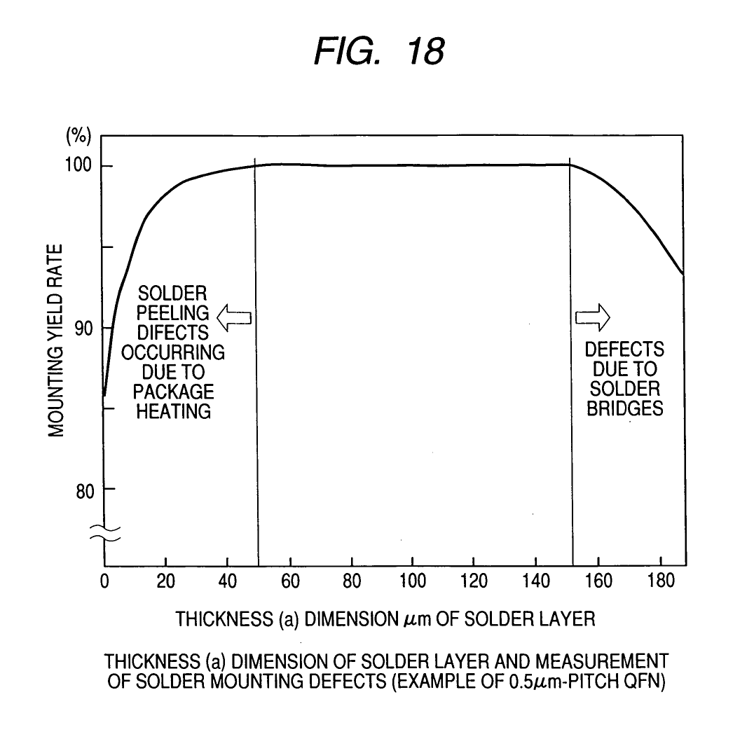

FIG. 18 is a graph showing the relation of solder peeling defects (product yield during mounting) to the solder layer height in QFN semiconductor devices where the terminals 6 are mounted at a pitch of 0.5 μm.

Solder peeling defects are also easily prone to occur due to warping of the package during mounting when the solder layer 10 has a thickness of 50 μm or less, as shown in FIG. 18. However solder bridges tend to easily occur when the solder layer 10 thickness is 150 μm or more. Due to these problems, the solder layer 10 is preferably formed in an arc shape of a/b≦½ with the solder layer 10 height set as a, and the solder layer 10 width set as b.

Solder peeling defects during mounting of the QFN semiconductor device 1 can therefore be suppressed in this way in the first embodiment.

Solder bridge defects during mounting of the QFN semiconductor device 1 also can be suppressed in this way in the first embodiment.

The solder bridge defects and solder peeling defects which occur during mounting can therefore be suppressed so that the QFN semiconductor device 1 product yield during mounting is improved.

Many pins can also be used in the QFN semiconductor device 1, since the solder bridge defects are eliminated.

In the first embodiment, the QFN semiconductor device 1 was mounted by melting the solder layer 10 and the solder paste member 32. However, the QFN semiconductor device 1 can also be mounted by using a solder paste material having a lower melting point than the solder layer 10 and by melting only the solder paste material, rather than the solder layer 10. The method yields the same effect as the first embodiment.

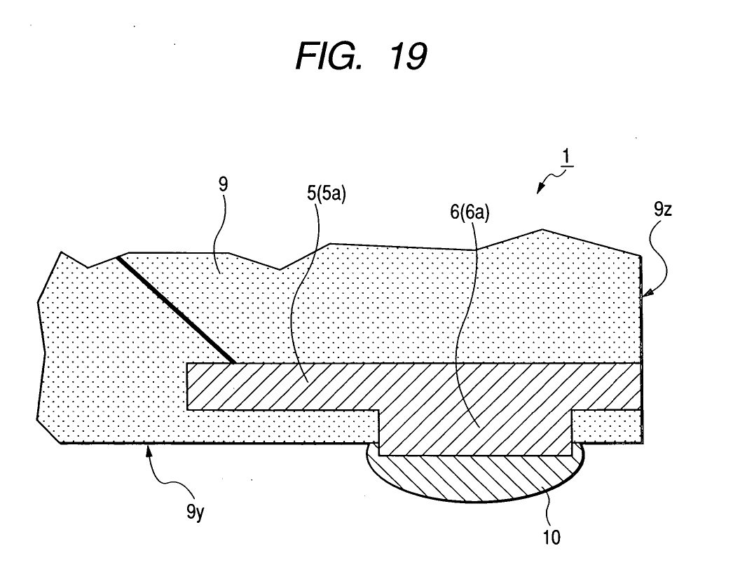

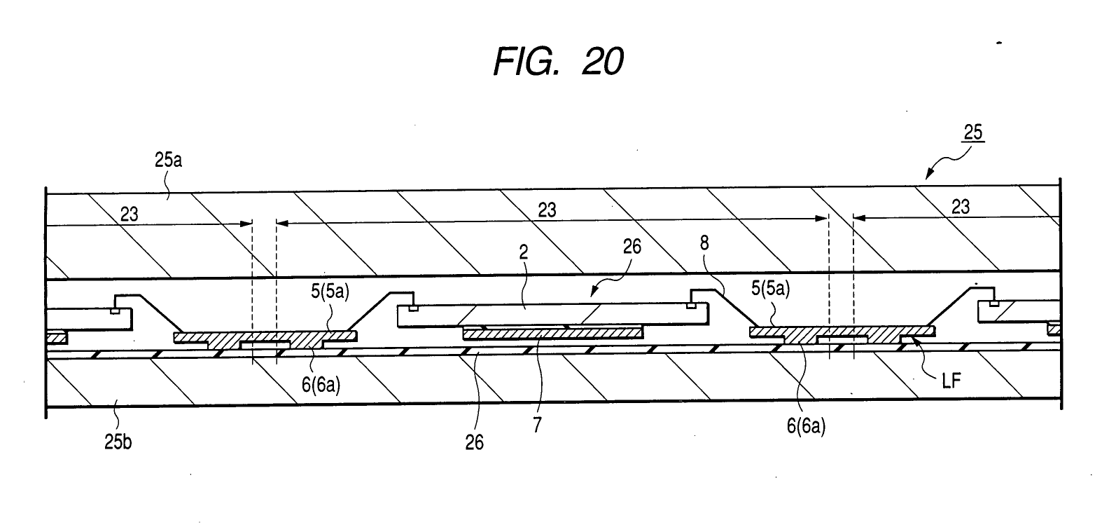

FIG. 19 and FIG. 20 show a variation of the QFN semiconductor device of the first embodiment of the present invention. FIG. 19 is a cross sectional view showing a portion of the QFN semiconductor device. FIG. 20 is a cross sectional view showing the lead frame while positioned in the metal mold during the course of manufacture of the semiconductor device.

As shown in FIG. 19, the terminal 6 of lead 5 protrudes out to a greater extent than the rear surface 9y of the plastic casing 9. The solder layer 10 is formed to cover the side surface and the joint surface of the terminal 6. In the molding process, as shown in FIG. 20, the terminal 6, which protrudes out beyond the rear surface 9y of the plastic casing 9, can be formed by positioning the lead frame LF in the metal mold 25, while a sheet 29a is interposed between the rear surface of the lead frame LF and the mating surface of the lower mold 25b. A resin piece which is capable of withstanding the hot temperatures present during molding and is capable of being crushed by the mold tightening force (clamp pressure, squeeze pressure) of the metal mold, may, for example, be used as the sheet 29a.

By using a method identical to that of the first embodiment, the solder paste member 32 can be formed on the joining surface of the terminal 6, while the terminal 6 protrudes from the rear surface 9y of the plastic casing 9, by melting the solder paste member 32 to form the solder layer 10, covering the side surface and joining surface of terminal 6.

In this variation (or adaptation), the same effect is obtained as described with reference to the first embodiment. After mounting the semiconductor device 1, the solder layer on the joint 34, which connects the terminal 6 of semiconductor device 1 with the electrode pad 31 of the printed circuit board 30, covers the side surface of terminal 6 of the semiconductor device 1, so that the connection strength of the joint 34 is increased.

### Second Embodiment

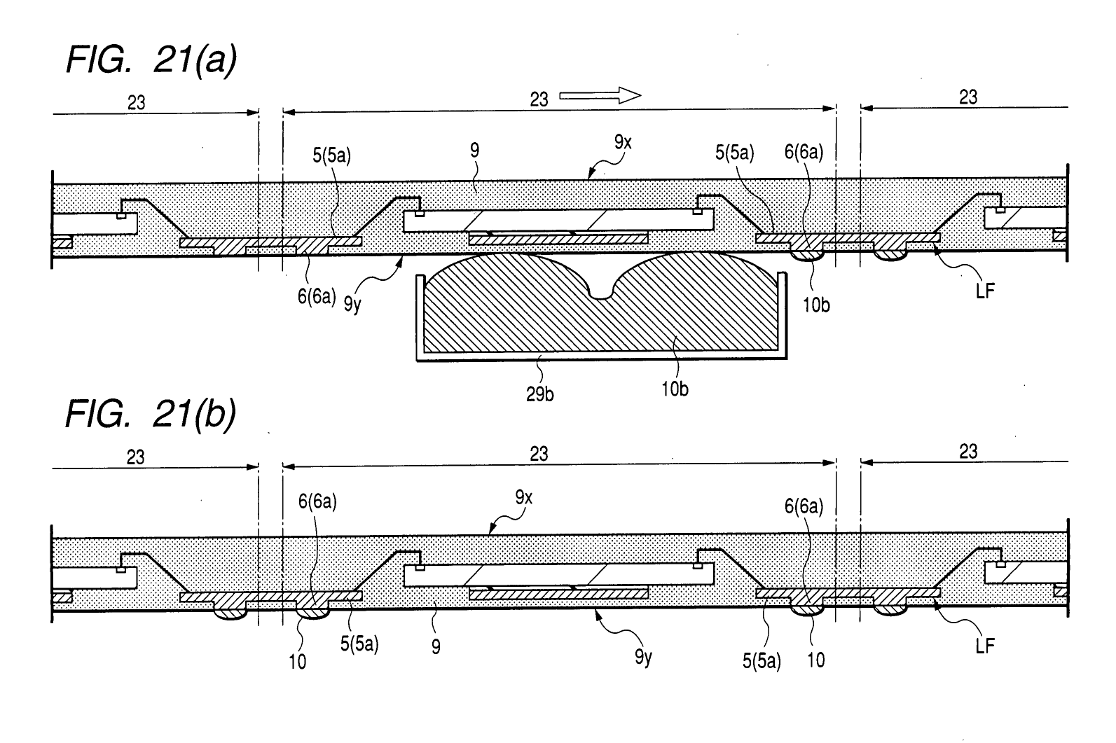

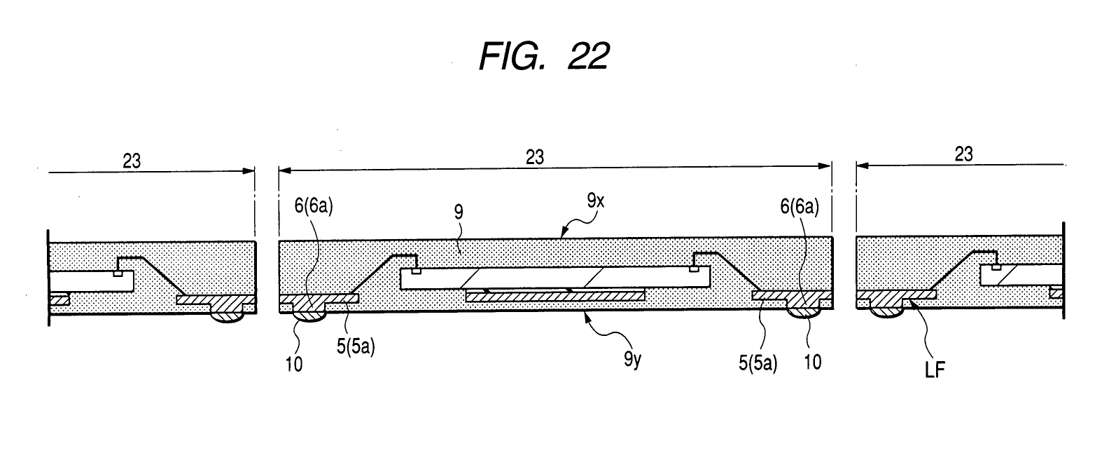

The step of forming the second layer 10 on the terminal 6 by melting the solder paste member 32 was described in conjunction with the first embodiment. However, in the second embodiment, a dip method for depositing the melted solder member onto the terminal 6 will be described with reference to FIGS. 21(a), 21(b) and FIG. 22.

FIG. 21(a) is a cross sectional view showing the solder layer forming process during manufacture of the semiconductor device. FIG. 21(b) is a cross sectional view showing the solder layer forming process during manufacture of the semiconductor device. FIG. 22 is a cross sectional view showing the segment forming process in the manufacture of the semiconductor device.

After forming the plastic casing 9 by a method identical to that used in the first embodiment, the terminals 6 are gradually made to come into contact with the molten solder member 10b, which is formed in a melted state in the solder tank 29b. The molten solder 10b is deposited on the terminal 6, and the molten solder is then solidified. The solder layer 10, which is in an arc shape and protrudes out beyond the rear surface 9y of the plastic casing 9, is formed in this way, as shown in FIG. 21(b), on each of the surfaces of the multiple terminals 6 that are exposed from the rear surface 9y of plastic casing 9. The thickness (amount of protrusion) of the solder layer 10 can easily be adjusted by changing the time during which the terminals 6 are in contact with the molten solder member 10b in the solder tank 28.

As shown in FIG. 22, the lead frame LF and the plastic casing 9 are segmented into product forming regions 23, for example, by dicing to form segments of the plastic casing 9. The semiconductor device of the second embodiment is mainly formed in this way.

The solder layer 10 in the second embodiment can also be formed in an arc shape with an a (solder layer height)/b (solder layer width)≦½, so that the same effect as in the first embodiment is obtained.

### Third Embodiment

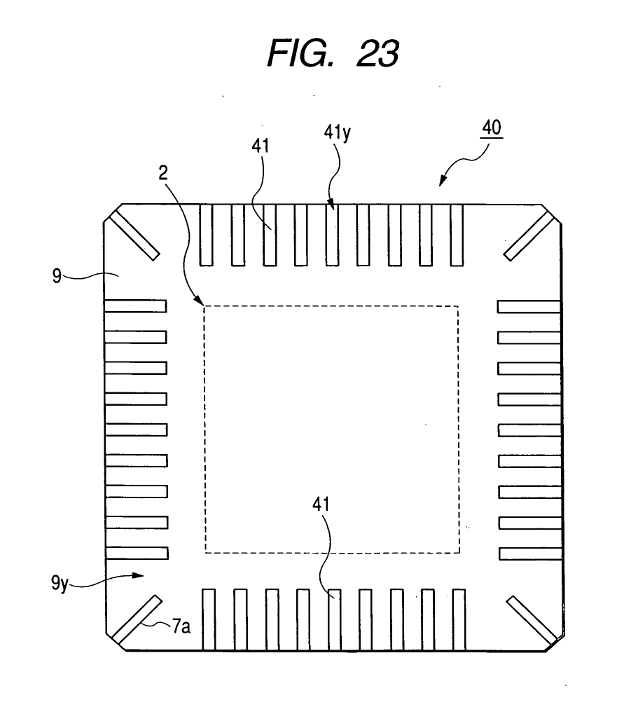

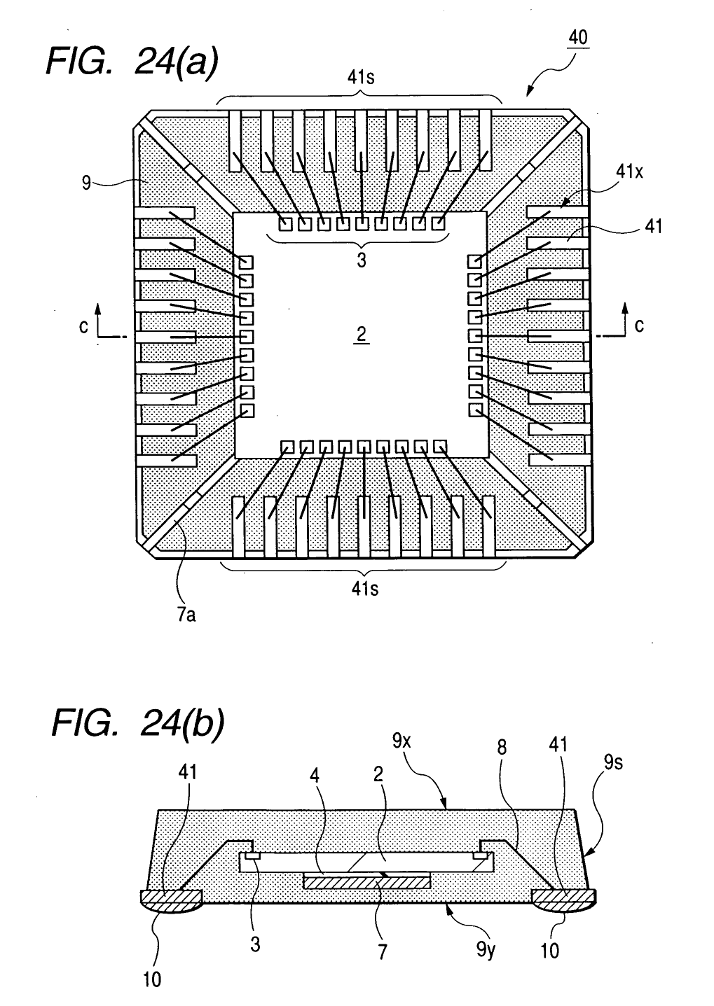

FIG. 23 through FIG. 25 illustrate a third embodiment of the present invention. FIG. 23 is a bottom view showing the external structure of the semiconductor device. FIG. 24(a) is a plan view and FIG. 24(b) is a cross-sectional view showing the internal structure of the semiconductor device.

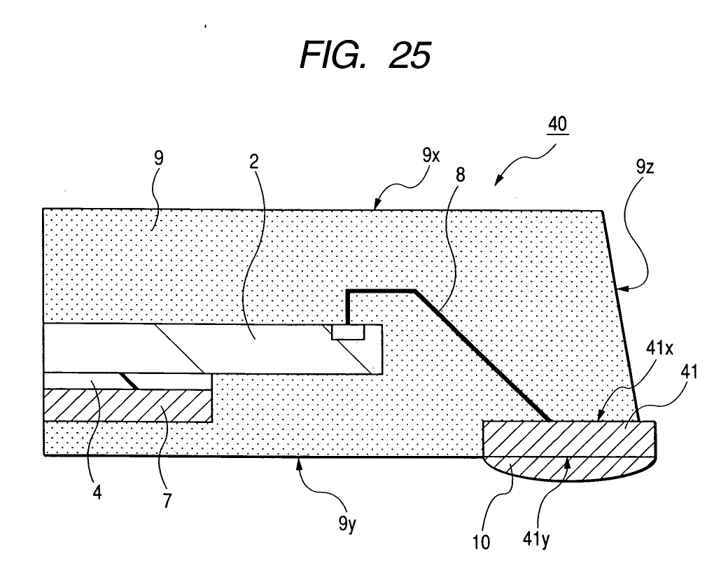

FIG. 25 is an enlarged cross sectional view showing a portion of FIG. 24(b).

As shown in FIG. 23 and FIGS. 24(a), 24(b), the semiconductor device 40 of the third embodiment has a package structure with multiple leads 41 formed along each of the sides of the plastic casing 9. On each of these multiple leads 41, the rear surface on the opposite side of the wire connection surface that is connected to the bonding wire 8 protrudes from the rear side of the plastic casing 9, and the multiple leads 41 are utilized as external terminals.

As shown in FIG. 25, a solder layer 10 is formed on each of the rear surfaces of the multiple leads 41 in an arc shape with an a (solder layer height)/b (solder layer width)≦½, the same as in the first embodiment. Even with the semiconductor device 40 configured as described above, the same effect as the first embodiment is obtained.

The inventors have described the present invention in detail with reference to various embodiments thereof. However, the present invention is not limited by these embodiments, and, needless to say, a diverse range of variations and adaptation are possible without departing from the scope and spirit of the invention.

For example, the present invention can be applied to SON type semiconductor devices, which are one type of non-lead semiconductor device utilizing a section of the leads exposed from the rear surface of the package as external terminals.

1. A method for mounting semiconductor devices comprising:
a process (a) for preparing the semiconductor devices by obtaining multiple terminals by exposing a section of each of multiple leads protruding from a rear side of a plastic casing, and forming a layer of solder by solidifying a molten solder material; and
a process (b) for supplying a solder paste material to multiple electrodes on a printed circuit board; and
a process (c) for melting the solder paste material of the multiple electrodes and connecting each of the multiple terminals with the multiple electrodes.

2. The method for mounting semiconductor devices according to claim 1, wherein, in the process (c), the solder layer on each of the multiple terminals is melted along with the solder paste material.

3. The method for mounting semiconductor devices according to claim 1, wherein the solder layer attains an arc shape of a/b≦½ when a solder layer height is set as a, and a solder layer width is set as b.

4. The method for mounting semiconductor devices according to claim 1, wherein
each of the multiple terminals protrudes from the rear side of the package, and
wherein the solder layer of each of the multiple terminals is formed to cover a side of each of the multiple terminals.

5. The method for mounting semiconductor devices according to claim 1, wherein the multiple leads are formed along sides of the plastic casing.

6. The method for mounting semiconductor devices according to claim 1, wherein
the multiple terminals include multiple first terminals formed along the sides of the plastic casing and multiple second terminals formed further inwards than the first terminals, and
wherein the multiple first and second terminals are formed in a repetitive array along a direction that the multiple leads are arrayed.

7. The method for mounting semiconductor devices according to claim 6, wherein
the multiple leads include multiple first leads formed along the sides of the plastic casing and multiple second leads arrayed between the first leads,
wherein each of the multiple first leads includes one of the first terminals, and
wherein each of the multiple second leads includes one of the second terminals.

8. (canceled)

9. (canceled)

10. (canceled)

11. (canceled)

12. (canceled)

13. (canceled)
